(19) United States
(12) Patent Application Publication
(10) Pub. No.: US 2015/0259827 A1
(43) Pub. Date: Sep. 17, 2015

(54) SUSCEPTOR

(71) Applicant: EPISTAR CORPORATION, Hsinchu (TW)

(72) Inventors: Tzu-Ching Yang, Hsinchu (TW); Yi-Lung Chen, Hsinchu (TW)

(73) Assignee: EPISTAR CORPORATION, Hsinchu (TW)

(21) Appl. No.: 14/215,897

(22) Filed: Mar. 17, 2014

(51) Int. Cl. C30B 25/12; C23C 16/458

(52) U.S. Cl. CPC C30B 25/12; C23C 16/458

(57) ABSTRACT

A susceptor, comprises: a bottom structure comprising atop surface; and a top structure detachably attached to the bottom structure comprising: a central part; and a peripheral part surrounding the central part and comprising a lower surface facing the bottom structure, wherein an outermost part of the lower surface distal from the central part is exposed and a part of the lower surface between the outermost part of the lower surface and the central part is connected to the top surface.

### TECHNICAL FIELD

The disclosure relates to a susceptor, and more particularly to a susceptor with a prolonged lifetime for an epitaxial growth system.

### DESCRIPTION OF BACKGROUND ART

Semiconductor optoelectronic devices contribute to data transmission and energy conversion along with the advance of technology. For example, the semiconductor optoelectronics devices are applicable to various systems such as the optical fiber communication, optical storage, and military system. In general, a process of forming semiconductor optoelectronic devices comprises steps of providing wafers, growing epitaxial layers, growing thin films, diffusion/ion implantation, photolithography and etching.

In the mentioned processes, growing epitaxial layers are generally carried out by a chemical vapor deposition (CVD) system or a molecular beam epitaxy (MBE) system, wherein the CVD system is preferred in the semiconductor industry because of its higher production rate than the MBE system.

FIG. 15 shows a conventional susceptor used in the CVD system. Referring to FIG. 16, the conventional susceptor comprises an upper structure 30 and a lower structure 40 detachably connected to the upper structure 30, wherein the upper structure 30 comprises a silicon carbide (SIC) coating on graphite. The upper structure 30 comprises a top surface 301, a lower surface 302 opposite to the top surface 301, a side surface 303 between the top surface 301 and the lower surface 302, and a protrusion 304 extending from the lower surface 302 toward the lower structure 40. The lower structure 40 comprises an upper surface 401 detachably connected to the lower surface 302 of the upper structure 30. An edge of the lower surface 302 contacts the upper surface 401 when the upper surface 401 is connected to the lower surface 302.

Referring to FIG. 16 and FIG. 17, the upper structure 30 further comprises a bulge 305 protruding toward the lower structure 40 from an outer part of the lower surface 302, and the lower structure 40 further comprises a recess 402 formed in an outer part of the upper surface 401 and is engaged with the bulge 305 for securing the upper structure 30 and the lower structure 40.

The disadvantages of the conventional susceptor include that the edge of the lower surface 302 contacting the upper surface 401 easily results in cracks in the SIC coating, wherein the cracks starts from the edge of the lower surface 302 and extends along the side surface 303 to the top surface 301. Such cracks lead to non-uniform heating, and thus the susceptor can not be re-used in consideration of the quality. Besides, since the bulge 305 and the recess 402 are exposed and thus subjected to the deposition environment in the CVD system, the material is deposited around the bulge 305 and the recess 402 during the process and thus the upper structure 30 and the lower structure 40 are adhered to each other. Accordingly, the susceptor is beyond repair since the upper structure 30 cannot be separated from the lower structure 40 anymore.

### SUMMARY OF THE DISCLOSURE

A susceptor is disclosed, comprising: a bottom structure comprising atop surface; and atop structure detachably attached to the bottom structure comprising: a central part; and a peripheral part surrounding the central part and comprising a lower surface facing the bottom structure, wherein an outermost part of the lower surface distal from the central part is exposed and a part of the lower surface between the outermost part of the lower surface and the central part is connected to the top surface.

### BRIEF DESCRIPTION OF THE DRAWINGS

FIG. 1 illustrates a susceptor in accordance with one of the embodiments of the present application;

FIG. 2 illustrates an exploded view of a susceptor in accordance with one of the embodiments of the present application;

FIG. 3 illustrates a cross-sectional view of a susceptor in accordance with one of the embodiments of the present application;

FIG. 4 illustrates a cross-sectional diagram showing an enlarged detail of region I in FIG. 3;

FIG. 5 illustrates a cross-sectional of a susceptor in accordance with one of the embodiments of the present application;

FIG. 6 illustrates a cross-sectional and exploded view of a susceptor in accordance with one of the embodiments of the present application;

FIG. 7 illustrates a cross-sectional view of a susceptor in accordance with one of the embodiments of the present application;

FIG. 8 illustrates a cross-sectional view of a susceptor in accordance with one of the embodiments of the present application;

FIG. 9 illustrates a cross-sectional view of a susceptor in accordance with one of the embodiments of the present application;

FIG. 10 illustrates a cross-sectional view of a susceptor in accordance with one of the embodiments of the present application;

FIG. 11 illustrates a cross-sectional view of a susceptor in accordance with one of the embodiments of the present application;

FIG. 12 illustrates an exploded view of a susceptor in accordance with one of the embodiments of the present application;

FIG. 13 illustrates a part of a susceptor in accordance with one of the embodiments of the present application;

FIG. 14 illustrates a cross-sectional view of an application of the susceptor in accordance with one of the embodiments of the present application;

FIG. 15 illustrates a cross-sectional view of a conventional susceptor;

FIG. 16 illustrates a partial side view of a conventional susceptor;

FIG. 17 illustrates a partial side view of a conventional susceptor; and

FIG. 18 illustrates a cross-sectional view of a conventional susceptor.

### DETAILED DESCRIPTION OF PREFERRED EMBODIMENTS

Exemplary embodiments of the present application will be described in detail with reference to the accompanying drawings hereafter. The following embodiments are given by way of illustration to help those skilled in the art fully understand the spirit of the present application. Hence, it should be noted that the present application is not limited to the embodiments herein and can be realized by various forms. Further, the drawings are not precise scale and components may be exaggerated in view of width, height, length, etc. Herein, the similar or identical reference numerals will denote the similar or identical components throughout the drawings.

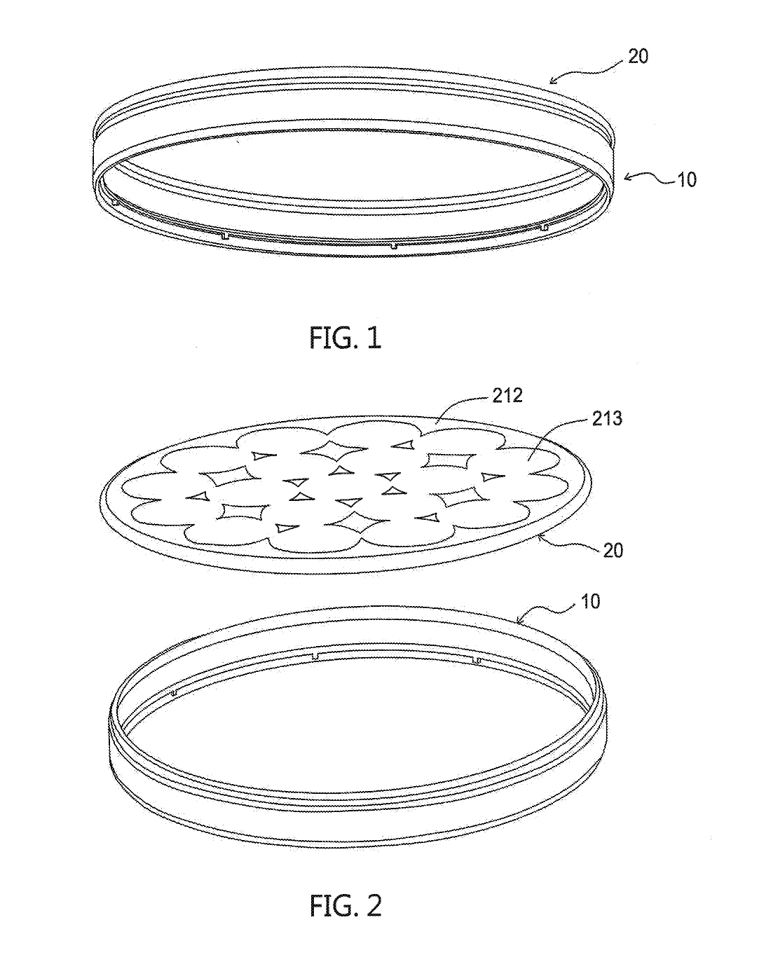

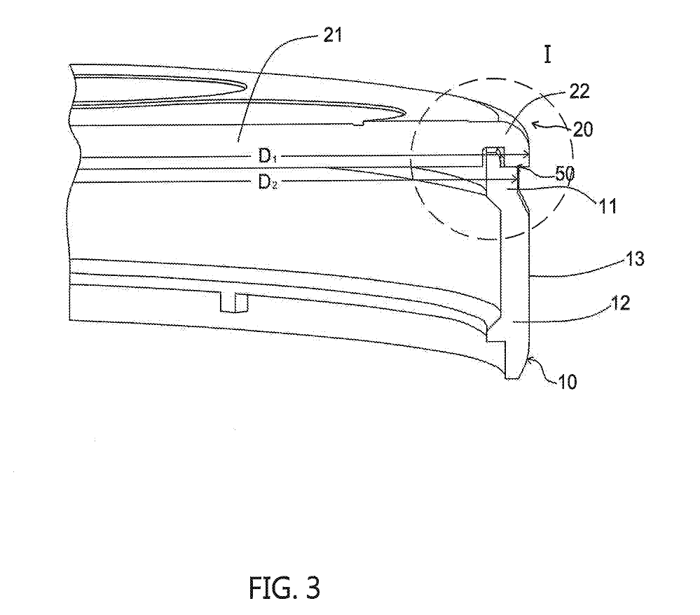

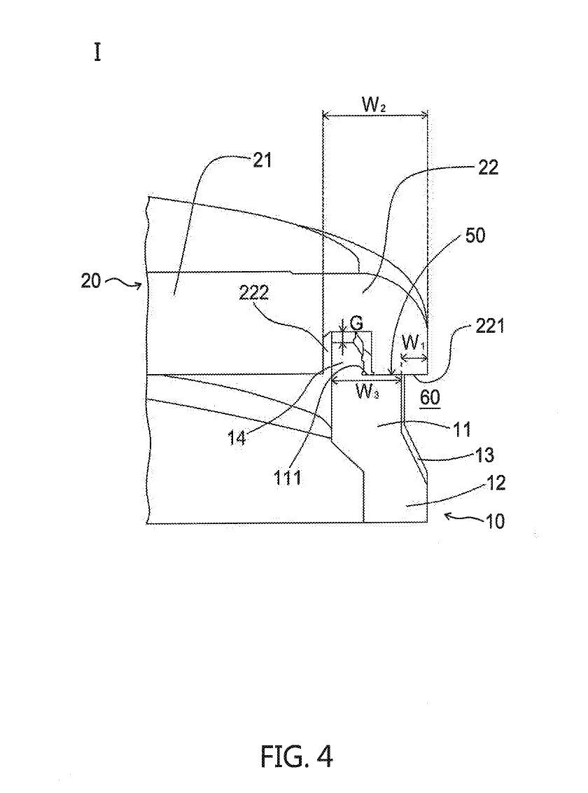

FIG. 1 illustrates a susceptor comprising a bottom structure 10 attached to a top structure 20. FIG. 2 illustrates an exploded view of a susceptor. FIG. 3 illustrates a cross-sectional view of an enlarged detail of a susceptor. FIG. 4 illustrates a cross-sectional diagram showing an enlarged detail of region I in FIG. 3. Referring to FIG. 1 to FIG. 4, a susceptor in accordance with one of the embodiments of the present application comprises a bottom structure 10 and atop structure 20 detachably attached to the bottom structure 10 to form a joint region 50. In one of the embodiments of the present application, a material of the top structure 20 or/and of the bottom structure 10 comprise boron nitride. The top structure 20 comprises silicon carbide (SiC) coating on boron nitride. The bottom structure 10 as a ring comprises an upper part 11 and a base part 12 connected to the upper part 11, wherein the upper part 11 comprises atop surface 111 opposite to the base part 12. The top structure 20 as a disc comprises a central part 21 and a peripheral part 22 surrounding the central part 21. Specifically, the peripheral part 22 forms the joint region 50 when attached to the bottom structure 10. The peripheral part 22 comprises a lower surface 221 facing the bottom structure 10.

An outermost part of the lower surface 221 distal from the central part 21 is unsheltered by the bottom structure 10 and thus is exposed. A part of the lower surface 221 between the outermost part of the lower surface 221 and the central part 21 is connected to the top surface 111 to form the joint region 50. Specifically, a part of the peripheral part 22 is beyond the joint region 50 of the bottom structure 10 and the top structure 20 to form a step that is exposed. In the present embodiment, a width W1 of the step is at least 1 mm, and preferably ranges from 1 to 10 mm. A part of the upper part 11 is closer to the central part 21 than the base part 12 of the bottom structure 10 so as to form a space 60 between the lower surface 221 that is exposed, the upper part 11 and the base part 12. Specifically, the bottom structure 10 further comprises an outer sidewall 13 extending from the upper part 11 to the base part 12. A part of the outer sidewall 13 comprises a slope different from that of the other part of the outer sidewall 13 so as to form the space 60 defined by the outer sidewall 13 and the step.

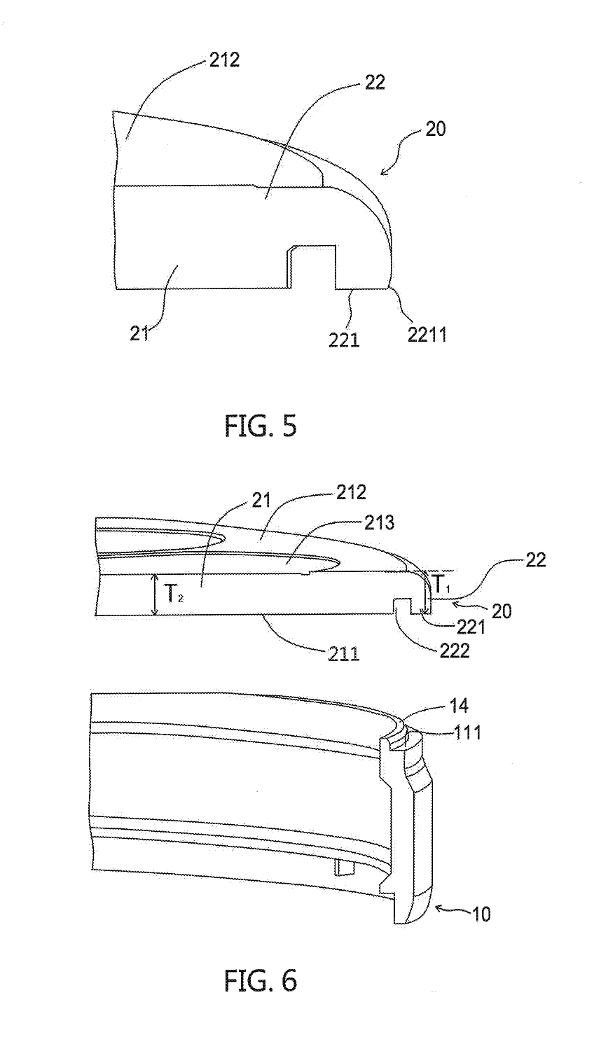

Referring to FIG. 3, in one of the embodiments of the present application, each of two opposite parts of the outer sidewall 13 comprises a slope different from that of the middle part of the outer sidewall 13. The top structure 20 can be easily separated from the bottom structure 10 by holding the step. Furthermore, since a part of the lower surface 221 is unsheltered by the bottom structure 10 and is exposed, probability of resulting cracks from the edge of the lower surface 221 is reduced. As a result, the susceptor disclosed in the present application has a prolonged lifetime. Besides, because the outer sidewall 13 comprises a part comprising a slope different from that of other parts, the resistance for gas flowing along the outer sidewall 13 is reduced while the gas flows out from the chamber in a CVD system, and turbulence in the gas flowing is further reduced. As FIG. 3 indicates, a maximum outer diameter D1 of the top structure 20 may be larger than an outer diameter D2 of the bottom structure 10. Furthermore, as FIG. 4 indicates, a maximum width W2 of the peripheral part 22 may be larger than a width W3 of the top surface 111. Optionally, the lower surface 22.1 shown in FIG. 5 comprises a rounded edge 2211 which is smooth and the most distant from the central part 21 so as to further reduce probability of resulting cracks from the rounded edge 2211.

FIG. 6 illustrates a cross-sectional and exploded view of an enlarged detail of a susceptor in accordance with one of the embodiments of the present application. The central part 21 comprises a bottom side 211, an upper side 212 with multiple concavities 213. The bottom side 211 is connected to the lower surface 221 of the peripheral part 22. The upper side 212 of the central part 21 is opposite to the bottom side 211. The multiple concavities 213 are for accommodating wafers. A maximum thickness T1 of the peripheral part 22 is not more than a maximum thickness T2 of the central part 21. The thickness of the peripheral part 22 is defined as a perpendicular distance between the upper side 212 of the central part 21 and the lower surface 221 of the peripheral part 22. The thickness of the central part 21 is defined as a distance between the bottom side 211 and the upper side 212. Compared to a conventional susceptor comprising the upper structure 30 as shown in FIG. 18, which comprises a maximum thickness T1 of the peripheral part 22 larger than a maximum thickness T2 of the central part 21, and the maximum thickness T1 results in a formation of an arc surface 31 leading to a removal of the portion shown by dashed line during the manufacturing of upper structure 30, wherein the removal is regarded as a waste of material. Furthermore, it is difficult to produce the arc surface 31. Accordingly, in the present embodiment, since the maximum thickness T1 of the peripheral part 22 is not more than a maximum thickness T2 of the central part 21, a waste of material is reduced during the manufacturing of the top structure 20. Besides, the arc surface 31 as shown in FIG. 18 is no longer necessary; the difficulty in producing the susceptor is reduced.

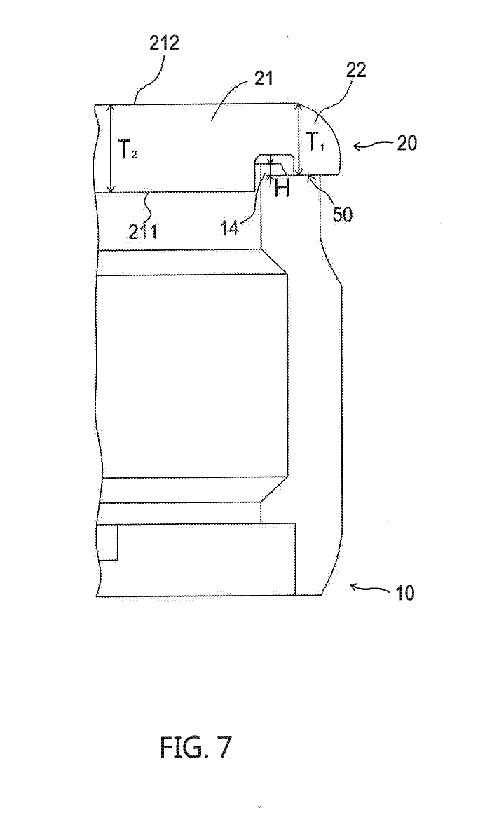

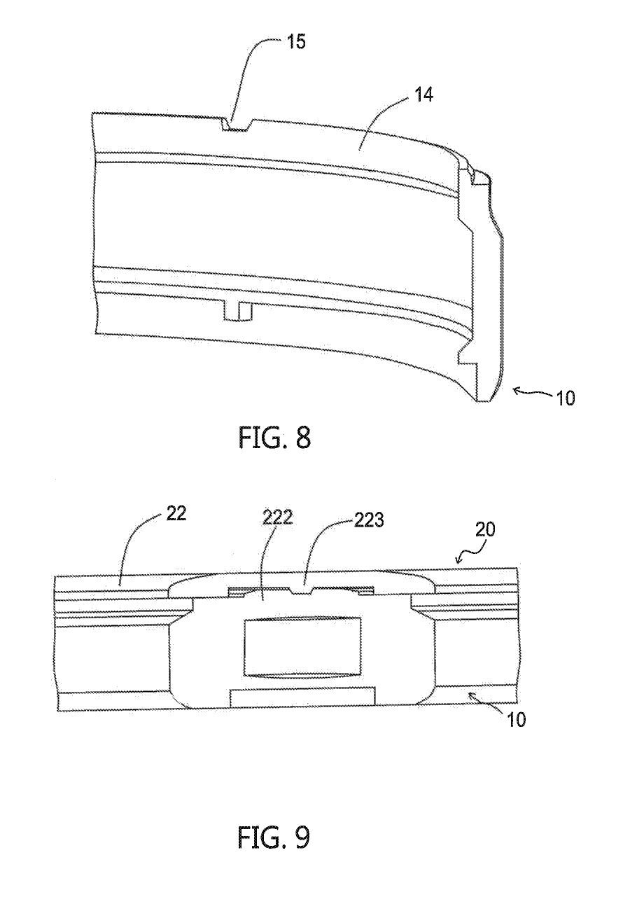

As FIG. 4 and FIG. 6 indicate, the susceptor comprises a first positioning structure 222 formed on the lower surface 221 of the peripheral part 22 of the top structure 20 and further comprises a second positioning structure 14 formed on the top surface 111. Specifically, the joint region 50 is between the exposed lower surface 221 and the second positioning structure 14. The first positioning structure 222 is associated with the second positioning structure 14 when the bottom structure 10 is attached to the top structure 20. In the present embodiment, the first positioning structure 222 comprises a concave part, and the second positioning structure 14 comprises a convex part wherein the convex part is associated with the concave part. The shapes of the concave part and the convex part are the same as the shape of the bottom structure 10. For example, the concave part and the convex part are circular. In the present embodiment, when the bottom structure 10 is attached to the top structure 20, the first positioning structure 222 and the second positioning structure 14 are covered by the peripheral part 22. Accordingly, during an epitaxial process in a CVD system, the first positioning structure 222 and the second positioning structure 14 are not directly exposed to the deposition environment, and therefore probability of materials deposited around the first positioning structure 222 and the second positioning structure 14 is reduced. Accordingly, the bottom structure 10 is easily separated from the top structure 20. In the present embodiment, the susceptor further comprises a gap G between the lower surface 221 and the second positioning structure 14 to reduce the contact area of the joint region 50. As a result, less heat is transferred to the bottom structure 10 through the joint region 50; the peripheral part 22 can keep the heat and thus reduces the temperature difference between the central part 21 and the peripheral part 22. Accordingly, the susceptor disclosed in the present application is advantageous of uniform heating. FIG. 7 illustrates a cross-sectional view of an enlarged detail of the susceptor in accordance with one of the embodiments of the present application. The height H of the convex part of the second positioning structure 14 can be adjusted with the maximum thickness T1 of the peripheral part 22. In the present embodiment, the maximum thickness T1 of the peripheral part 22 is less than a maximum thickness T2 of the central part 21, and the height H of the second positioning structure 14 is changed such that the joint region 50 is closer to the upper side 212 than the bottom side 211. Referring to FIG. 8 and FIG. 9, in one of the embodiments of the present application, the susceptor further comprises a first fastening structure 223 and a second fastening structure 15, wherein the first fastening structure 223 is formed on the first positioning structure 222 and the second fastening structure 15 is formed on the second positioning structure 14. The first fastening structure 223 is associated with the second fastening structure 15 when the top structure 20 is attached to the bottom structure 10. In the present embodiment, the first fastening structure 223 comprises one or multiple separated protrusions disposed in the concave part. The second fastening structure 15 comprises one or multiple separated notches formed in the convex part. Each of the notches is associated with one of the protrusions respectively. In the present embodiment, the first fastening structure 223 and the second fastening structure 15 are covered by the peripheral part 22 when the top structure 20 is attached to the bottom structure 10. Accordingly, when the CVD system performs the epitaxial process, the first fastening structure 223 and the second fastening structure 15 are not directly exposed to the deposition environment, and therefore the probability of materials deposited around the first fastening structure 223 and the second fastening structure 15 is reduced. Accordingly, the bottom structure 10 is easily separated from the top structure 20.

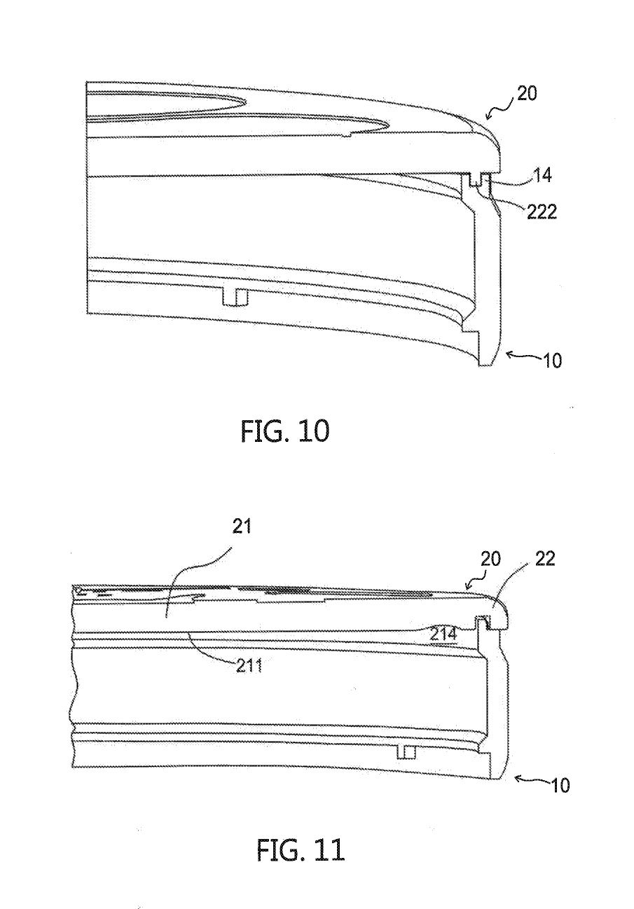

Referring to FIG. 10, in one of the embodiments of the present application, the first positioning structure 222 comprises a convex part, and the second positioning structure 14 comprises a concave part, wherein the convex part is associated with the concave part. In the present embodiment, the bottom structure 10 covers the first positioning structure 222. The first fastening structure (not shown) comprises one or multiple separated notches disposed formed in the convex part. The second fastening structure (not shown) comprises one or multiple separated protrusions formed on the concave part. Each of the notches is associated with one of the protrusions respectively.

Referring to FIG. 11, in one of the embodiments of the present application, the central part 21 further comprises a recess 214 formed on the bottom side 211, wherein the recess 214 is away from the center of the central part 21 and is close to the peripheral part 22. When the susceptor of the present embodiment is used in a CVD system, the recess 214 is for accommodating heaters so as to lead to a more uniform heating during an epitaxial process.

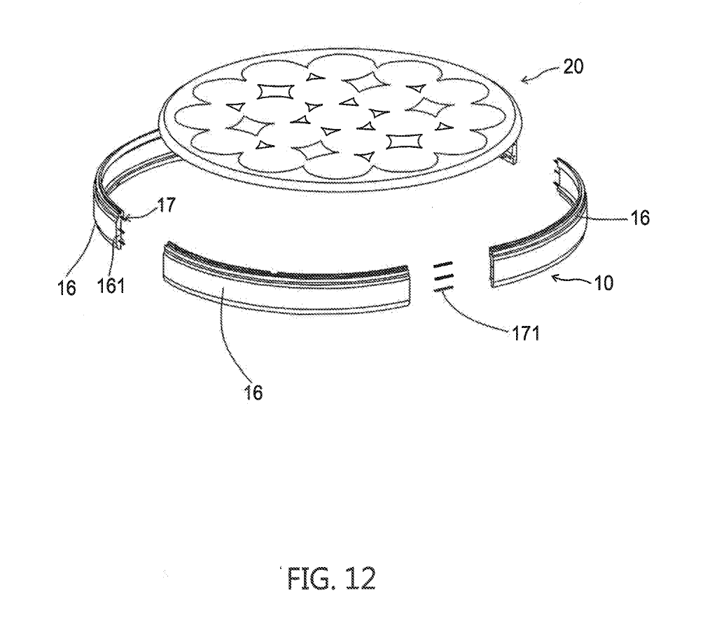

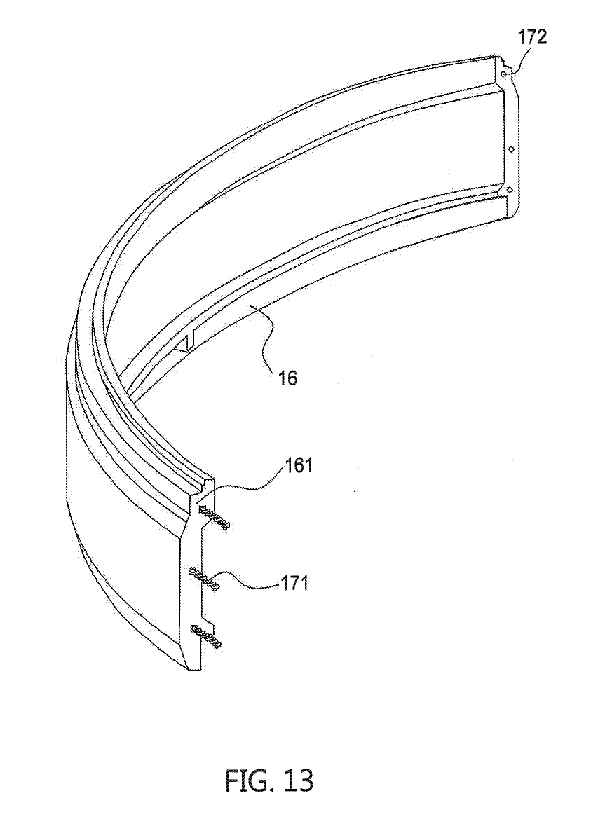

Referring to FIG. 12 and FIG. 13, in one of the embodiments of the present application, the bottom structure 10 comprises multiple sub-elements 16 having the same structure capable of detachably coupling with one another with fixing elements 17. The fixing elements 17 can be any structure for facilitating the coupling of the multiple sub-elements 16. For example, the fixing elements 17 comprise multiple detachable dowels 171 and multiple holes 172 formed on radial surfaces 161 of the sub-elements 16. When coupling any two sub-elements 16, each dowel 171 is inserted into one of the holes 172 of the adjacent sub-element 16. The difference between the coefficient of thermal expansion of the material of the dowel 171 and the material of the sub-element 16 and the size of the dowel 171 and the sub-element 16 are taken in to consideration and can be adjusted to avoid serious structural problems caused by the thermal expansion when the susceptor is used in the CVD system. In the present embodiment, the material of the dowel 171 comprises alloy of Mo and W. In the present embodiment, if one of the sub-elements is broken, another new sub-element can replace the broken one instead of changing a whole integrated bottom structure 10 since the sub-elements 16 are capable of detachably coupling with one another, and thus the susceptor of the present embodiment is cost-effective.

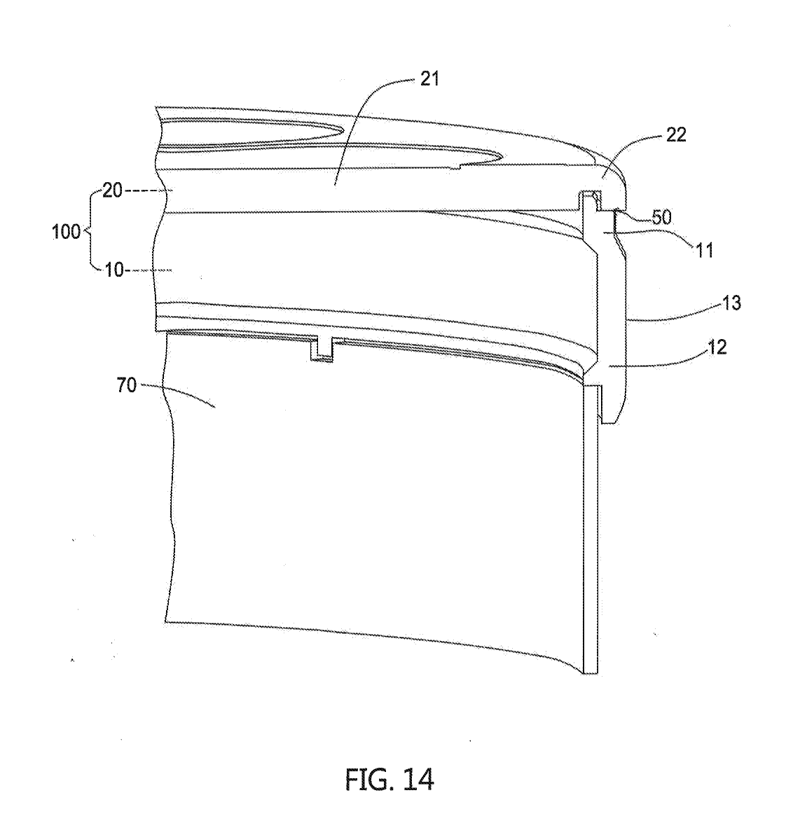

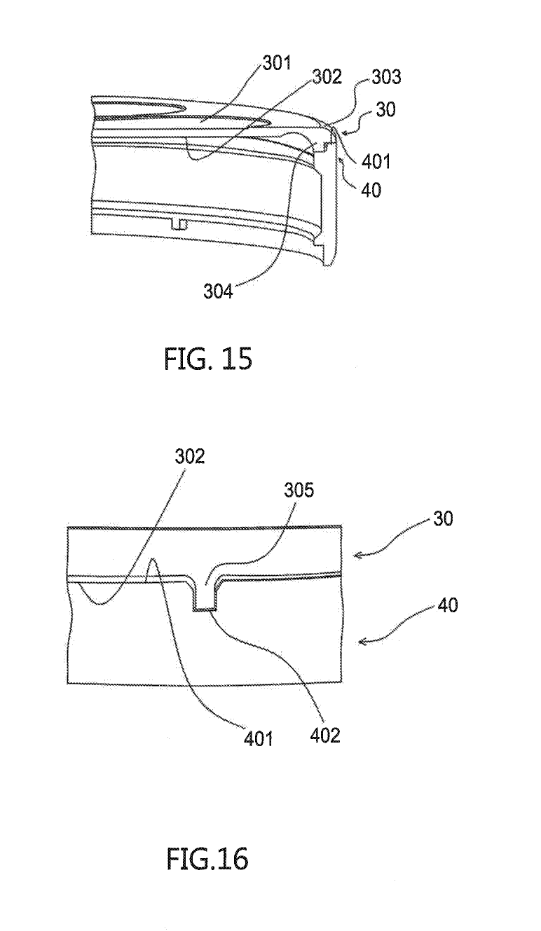

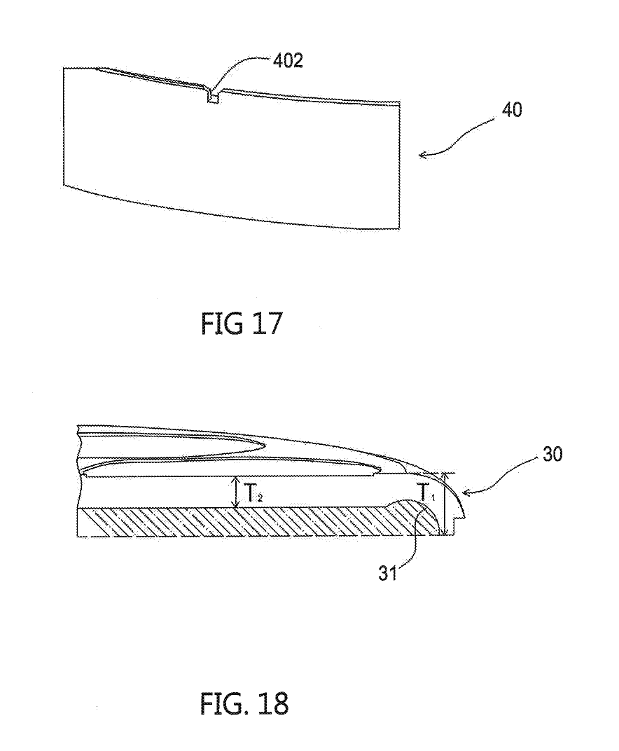

FIG. 14 illustrates a cross-sectional view of an application of the susceptor 100 accordance with one of the embodiments of the present application. The susceptor 100 is attached to a susceptor support 70 comprising quartz when used in a CVD system.

The foregoing description of preferred and other embodiments in the present application is not intended to limit or restrict the scope or applicability of the inventive concepts conceived by the Applicant. In exchange for disclosing the inventive concepts contained herein, the Applicant desires all patent rights afforded by the appended claims. Therefore, it is intended that the appended claims include all modifications and alterations to the full extent that they come within the scope of the following claims or the equivalents thereof.

What is claimed is:

1. A susceptor, comprising:
a bottom structure comprising atop surface; and
a top structure detachably attached to the bottom structure comprising:
a central part; and
a peripheral part surrounding the central part and comprising a lower surface facing the bottom structure, wherein an outermost part of the lower surface distal from the central part is exposed and a part of the lower surface between the outermost part of the lower surface and the central part is connected to the top surface.

2. The susceptor according to claim 1, further comprises a first positioning structure formed on the top structure and a second positioning structure formed on the bottom structure and associated with the first positioning structure.

3. The susceptor according to claim 2, wherein the first positioning structure comprises a concave part, and wherein the second positioning structure comprises a convex part associated with the concave part.

4. The susceptor according to claim 3, further comprises a first fastening structure connected to the first positioning structure, and comprises a second fastening structure connected to the second fastening structure and associated with the first fastening structure.

5. The susceptor according to claim 4, wherein the first fastening structure comprises one protrusion disposed in the concave part, and the second fastening structure comprises one notch formed in the convex part and associated with the protrusion.

6. The susceptor according to claim 2, wherein the peripheral part covers the first positioning structure and the second positioning structure.

7. The susceptor according to claim 2, further comprises a gap between the lower surface and the second positioning structure.

8. The susceptor according to claim 1, wherein the bottom structure comprises multiple sub-elements having the same structure.

9. The susceptor according to claim 8, wherein the sub-elements are capable of detachably coupling with one another.

10. The susceptor according to claim 1, wherein the peripheral part and the central part have a maximum thickness respectively, wherein the maximum thickness of the peripheral part is not more than the maximum thickness of the central part.

11. The susceptor according to claim 1, wherein the central part comprises a bottom side and a recess formed on the bottom side, wherein the recess is close to the peripheral part.

12. The susceptor according to claim 1, wherein a material of the top structure and/or a material of the bottom structure comprise boron nitride.

13. The susceptor according to claim 1, wherein the bottom structure comprises an upper part and a base part connected to the upper part, wherein the upper part comprises the top surface formed thereon, and the upper part is closer to the central part than the base part so as to form a space between the lower surface that is exposed, the upper part and the base part.

14. The susceptor according to claim 1, wherein the peripheral part has a maximum width and the top surface has a width, wherein the maximum width of the peripheral part is larger than the width of the top surface.

15. The susceptor according to claim 1, wherein the lower surface comprises a rounded edge the most distant from the central part.

16. The susceptor according to claim 1, wherein the top structure and the bottom structure are circular, and wherein the top structure has a maximum outer diameter and the bottom structure comprises an outer diameter, wherein the maximum outer diameter of the top structure is larger than the outer diameter of the bottom structure.

17. A susceptor, comprising:
a bottom structure as a ring comprising an outer sidewall; and
a top structure as a disc detachably attached to the bottom structure at a joint region;
wherein a part of the top structure is beyond the joint region to form a step that is exposed.

18. The susceptor according to claim 17, further comprising a space defined by the outer sidewall and the step.

19. The susceptor according to claim 17, wherein the top structure comprises a concave part at the joint region and wherein the bottom structure comprises a convex part associated with the concave part.

20. The susceptor according to claim 17, wherein a part of the outer sidewall comprises a slope different from that of the other part of the outer sidewall.
